(19) United States
(12) Patent Application Publication
(10) Pub. No.: US 2010/0291319 A1
(43) Pub. Date: Nov. 18, 2010

(54) PLASMA PROCESSING APPARATUS AND PLASMA PROCESSING METHOD

(75) Inventors: Jun Yamashita, Hyogo (JP); Yoshiro Kabe, Hyogo (JP); Junichi Kitagawa, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/680,645

(22) PCT Filed: Sep. 29, 2008
(86) PCT No.: PCT/JP2008/067611

§ 371 Date: May 25, 2010

(30) Foreign Application Priority Data
Sep. 29, 2007 (JP) 2007-256964

(51) Int. Cl. C23C 16/511; C23C 16/00

(52) U.S. Cl. 427/575; 118/723 R; 118/723 AN

(57) ABSTRACT

A plasma processing apparatus for plasma-processing a target substrate is provided. The plasma processing apparatus includes a metallic processing container forming a processing space in which a plasma process is performed, and a substrate mounting table provided in the processing space to mount a target substrate thereon, a quartz member which shields a sidewall of the metallic processing container from the processing space and whose lower end extends to a position lower than a substrate mounting surface of the substrate mounting table, an annular member which is made of quartz and is provided between a bottom surface of the quartz member and a bottom wall of the metallic processing container to shield the bottom wall of the metallic processing container from the processing space, and a processing gas inlet part for introducing a processing gas into the processing space from a vicinity of an outer periphery of the substrate mounting table.

### FIELD OF THE INVENTION

The present invention relates to a processing apparatus and a processing method for performing a process on a target substrate such as a semiconductor wafer; and, more particularly, to a plasma processing apparatus and a plasma processing method for performing a plasma process on a target substrate by using a plasma.

### BACKGROUND OF THE INVENTION

In recent years, a design rule of large scale integration (LSI) semiconductor devices is getting finer to meet the demand for higher integration and higher speed LSI. Further, the size of semiconductor wafers is increasing to improve production yield. Along with these trends, an apparatus for performing a process on a target substrate such as a semiconductor wafer is required to cope with the miniaturization of the devices and an increase in the size of the wafers.

In a recent semiconductor process, a plasma processing apparatus is commonly used for film formation and etching. Particularly, growing attention has been paid to a plasma processing apparatus capable of generating a plasma having a low electron temperature in a high density (see, e.g., Japanese Patent Application Publication No. 2003-133298).

However, when the substrate is directly oxidized or nitrified by using the plasma processing apparatus, a processing rate such as an oxidation rate or nitration rate is low. Further, a metallic member is used for a processing container and, thus, metal contamination may occur by a plasma action.

### SUMMARY OF THE INVENTION

It is an object of the present invention to provide a plasma processing apparatus and a plasma processing method capable of achieving a high processing rate.

In accordance with a first aspect of the present invention, there is provided a plasma processing apparatus including a metallic processing container forming a processing space in which a plasma process is performed; a substrate mounting table provided in the processing space to mount a target substrate thereon; a quartz member which shields a sidewall of the metallic processing container from the processing space and whose lower end extends to a position lower than a substrate mounting surface of the substrate mounting table; an annular member which is made of quartz and is provided between a bottom surface of the quartz member and a bottom wall of the metallic processing container to shield the bottom wall of the metallic processing container from the processing space; and a processing gas inlet section for introducing a processing gas into the processing space from a vicinity of an outer periphery of the substrate mounting table.

In accordance with a second aspect of the present invention, there is provided a plasma processing apparatus including a metallic processing container forming a processing space in which a plasma process is performed; a substrate mounting table provided in the processing space to mount a target substrate thereon; a quartz ceiling plate provided at an upper portion of the processing container to face a substrate mounting surface of the substrate mounting table and having a cylindrical portion which shields a sidewall of the metallic processing container from the processing space; a microwave antenna coupled to the quartz ceiling plate; a quartz plate which is provided between a bottom surface of the cylindrical portion and a bottom wall of the metallic processing container to shield the bottom wall of the metallic processing container from the processing space; and a processing gas inlet section for introducing a processing gas into the processing space from a vicinity of an outer periphery of the substrate mounting table.

In accordance with a third aspect of the present invention, there is provided a plasma processing method for forming a film by using a microwave plasma, the method including supplying a microwave to a dielectric enclosing an outer periphery or an upper surface of a target substrate and allowing a microwave to pass therethrough; and supplying a processing gas from the outer periphery of or below the target substrate while the microwave is supplied to the dielectric.

### BRIEF DESCRIPTION OF THE DRAWINGS

FIG. 1A is a horizontal cross sectional view schematically showing a plasma processing apparatus in accordance with an embodiment of the present invention.

FIG. 1B is a cross sectional view taken along line 1B-1B of FIG. 1A.

FIGS. 2A and 2B depict side views of the ceiling plate seen from the loading/unloading port.

FIGS. 3A and 3B present side views of the shutter seen from the loading/unloading port.

FIGS. 4A and 4B illustrate vertical movements of the shutter in conjunction with the gate valve.

FIG. 5 is an enlarged cross sectional view of the periphery of the processing gas inlet opening.

FIG. 6A depicts a plan view of the quartz plate.

FIG. 6B is a cross sectional view taken along line 6B-6B of FIG. 6A.

FIG. 7 illustrates an example of the RLSA plasma processing apparatus in accordance with the embodiment of the present invention.

FIG. 8A is a table showing the results of a silicon oxide film formation test.

FIG. 8B illustrates the results of a process for forming a silicon oxide film by using a conventional apparatus.

FIG. 9 illustrates the results of comparison between the results of FIG. 8A and the results of FIG. 8B.

FIG. 10 is a graph showing the results of FIG. 9.

FIG. 11A is a cross sectional view schematically showing the apparatus in accordance with the embodiment of the present invention.

FIG. 11B is a cross sectional view schematically showing the apparatus of the comparative example.

### DETAILED DESCRIPTION OF THE EMBODIMENTS

Hereinafter, embodiments of the present invention will be described in detail with reference to the accompanying drawings which form a part hereof.

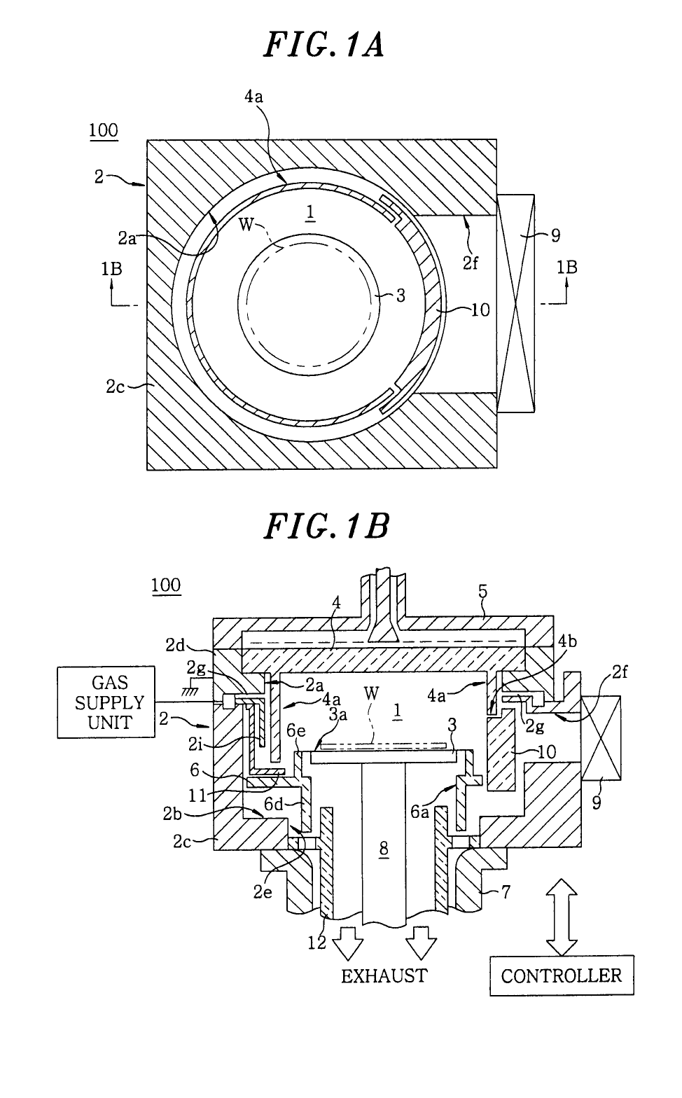

FIG. 1A is a horizontal cross sectional view schematically showing a plasma processing apparatus using a microwave plasma in accordance with an embodiment of the present invention. FIG. 1B is a cross sectional view taken along line 1B-1B of FIG. 1A.

The plasma processing apparatus shown in FIGS. 1A and 1B is a radial line slot antenna (RLSA) plasma processing apparatus 100. In the plasma processing apparatus 100, a microwave is generated and introduced into a processing chamber by using the RLSA such that a plasma having a low electron temperature of 2 eV or less is generated in a high density of 5×10¹⁰ to 1×10¹³/cm³ in the processing chamber.

The plasma processing apparatus 100 of the present embodiment includes a metallic processing container 2 forming a processing space 1 in which a plasma process is performed, a substrate mounting table 3 provided in the processing space 1 to mount a target substrate W thereon, and a ceiling plate 4 which is made of quartz, is provided at an upper portion of the processing container 2 to face a substrate mounting surface 3a of the substrate mounting table 3 and has a cylindrical portion 4a made of high purity quartz and having a function of shielding a sidewall 2a of the processing container 2 from the processing space 1. The plasma processing apparatus 100 further includes a microwave antenna 5 coupled to the ceiling plate 4 and a quartz plate which is made of high purity quartz and is provided between a bottom surface of the cylindrical portion 4a and a bottom wall 2b of the processing container 2 to shield the bottom wall 2b from the processing space 1.

The processing container 2 is made of, e.g., aluminum or an aluminum alloy. In this embodiment, the processing container 2 includes a processing chamber 2c and a grounded lid 2d. The lid 2d is airtightly placed on the processing chamber 2c and the ceiling plate 4 is airtightly placed on and supported by the lid 2d, thereby forming the airtight cylindrical processing space 1.

A circular opening 2e is formed at a substantially central portion of the bottom wall 2b of the processing chamber 2c. The bottom wall 2b is connected to a metallic gas exhaust room 7 via the opening 2e, the gas exhaust room communicating with the processing space 1. The gas exhaust room 7 is made of metal, e.g., aluminum or an aluminum alloy in the same way as the processing container 2, and, in the present embodiment, has a cylindrical shape.

Further, a supporting column 8 is disposed in the cylindrical gas exhaust room 7 to support a central portion of the substrate mounting table 3. The substrate mounting table 3 supported at a front end of the supporting column 8 is disposed in the processing space 1.

A loading/unloading port 2f through which the target substrate W is loaded into/unloaded from the processing space 1 is formed at a portion of the sidewall 2a of the processing container 2. A gate valve 9 capable of being opened and closed is attached to the loading/unloading port 2f. When the target substrate W is loaded into/unloaded from the processing space 1, the gate valve 9 is opened and the processing space 1 communicates with the outside. When the target substrate W is processed in the processing space 1, the gate valve 9 is closed and the processing space 1 is blocked from the outside.

The ceiling plate 4 is disposed on the lid 2d and airtightly fixed thereto. The ceiling plate 4 has a circular shape and the cylindrical portion 4a is provided to extend downward from a periphery of the ceiling plate 4 along the sidewall 2a of the processing container 2 in a curtain shape. The cylindrical portion 4a is formed integrally with the ceiling plate 4 and is made of high purity quartz in the same way as the ceiling plate 4.

The cylindrical portion 4a serves to shield the sidewall 2a from the processing space 1. However, as described above, the loading/unloading port 2f is formed at the portion of the sidewall 2a. If the cylindrical portion 4a blocks the loading/unloading port 2f, loading and unloading the target substrate W cannot be performed. Accordingly, a cutoff portion 4b is provided at a portion of the cylindrical portion 4a corresponding to the loading/unloading port 2f to enable the loading and unloading of the target substrate W.

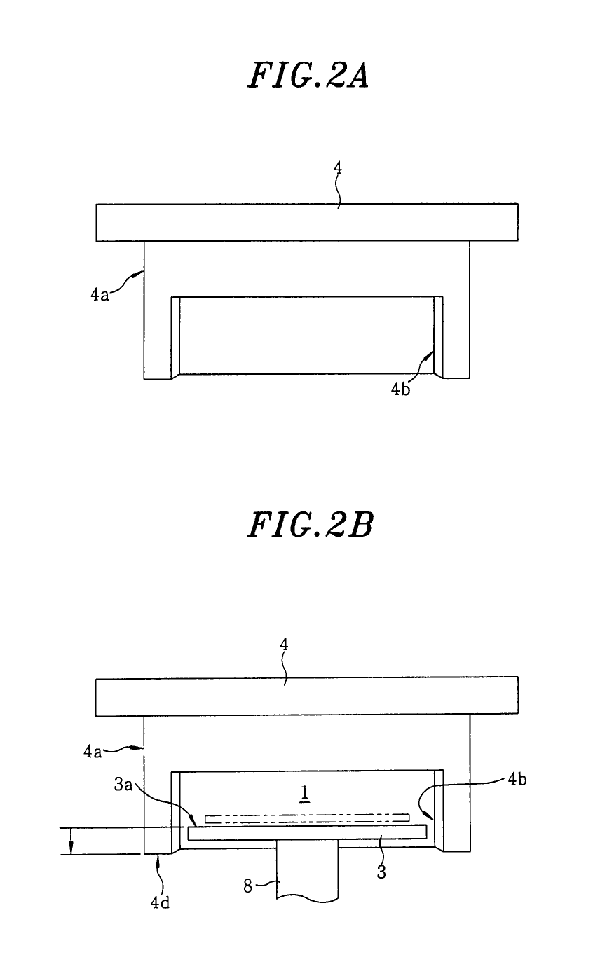

FIGS. 2A and 2B illustrate side views of the ceiling plate 4 seen from the loading/unloading port 2f. As shown in FIG. 2A, the cylindrical portion 4a of the ceiling plate is provided with the cutoff portion 4b corresponding to the loading/unloading port 2f.

Further, as shown in FIG. 2B, the bottom surface 4d of the cylindrical portion 4a is arranged at a position lower than the substrate mounting surface 3a of the substrate mounting table 3. By arranging the bottom surface 4d at a position lower than the substrate mounting surface 3a, a region above the target substrate W in which the plasma is particularly uniformly generated in the processing space 1 can be enclosed with the cylindrical portion 4a. Accordingly, the sidewall 2a of the metallic processing container 2 is prevented from being in contact with the plasma, thereby suppressing contamination due to metal scattered from the sidewall 2a.

At the outside of the processing container 2, as described above, the gate valve 9 made of metal such as aluminum, an aluminum alloy or the like is provided such that the loading/unloading port 2f is interposed between the cylindrical portion 4a and the gate valve 9. Because of the cutoff portion 4b provided in the cylindrical portion 4a, a portion of the sidewall 2a in the vicinity of the loading/unloading port 2f, an inner wall of the loading/unloading port 2f, and the gate valve 9 are exposed to the processing space 1.

In the present embodiment, a shutter 10 made of quartz is provided at a position corresponding to the cutoff portion 4b and facing the processing space 1. The shutter 10 covers not to expose the portion of the sidewall 2a in the vicinity of the loading/unloading port 2f, the inner wall of the loading/unloading port 2f, and the inner surface of the gate valve 9 to the processing space 1. Accordingly, the plasma is prevented from being in contact with the metallic members, thereby suppressing the metal contamination.

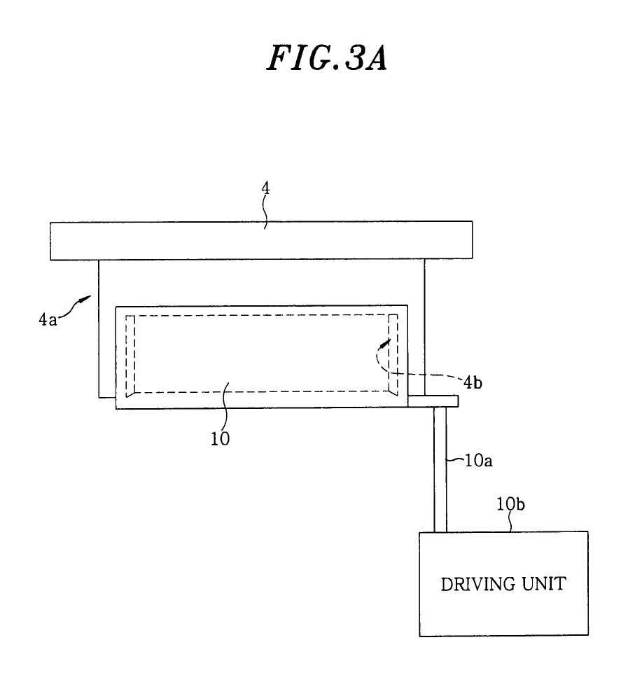

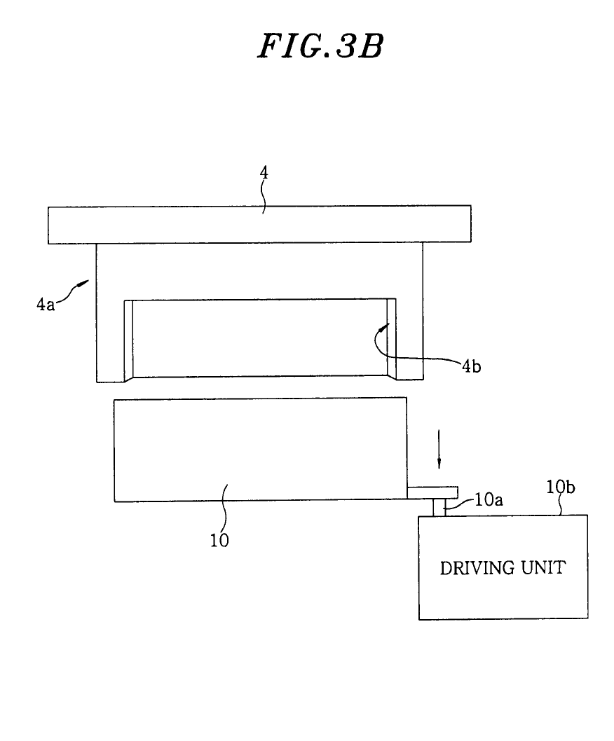

The shutter 10 vertically moves in conjunction with, e.g., opening/closing of the gate valve 9. When the gate valve 9 is closed, the shutter 10 is moved up to shield the cutoff portion 4b. On the other hand, when the gate valve 9 is opened, the shutter 10 is moved down to disclose the cutoff portion 4b. FIGS. 3A and 3B illustrate side views of the shutter 10 seen from the loading/unloading port 2f.

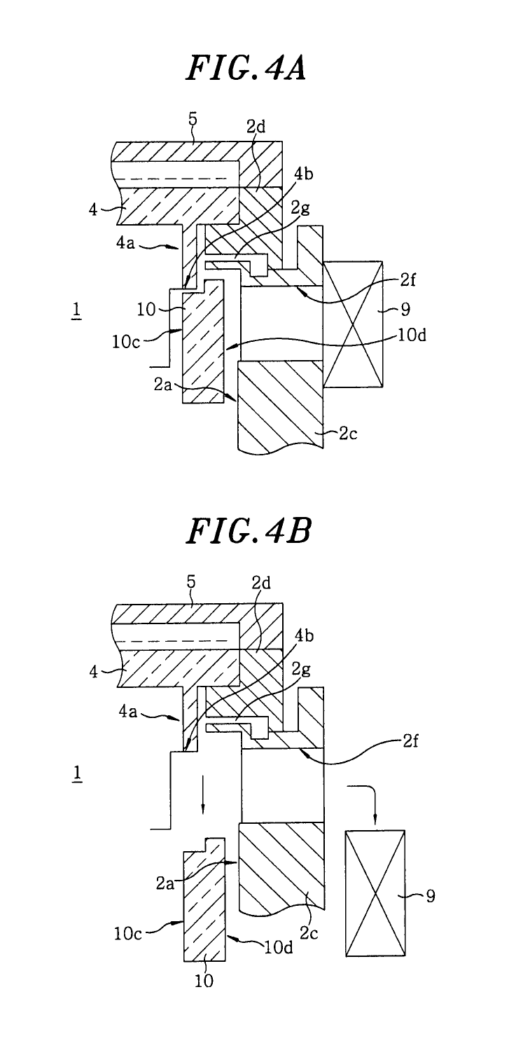

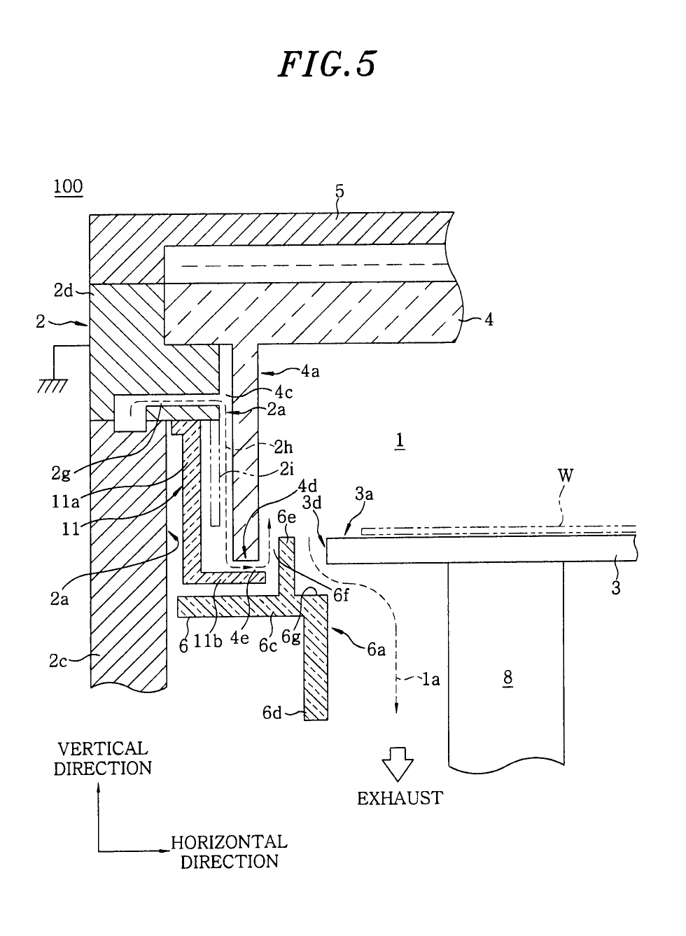

As shown in FIGS. 3A and 3B, the shutter 10 is connected to a driving unit 10b via a shaft 10a. The driving unit 10b vertically moves the shaft 10a, thereby vertically moving the shutter 10 installed at a front end of the shaft 10a. FIG. 3A shows the shutter 10 moved up and FIG. 3B shows the shutter 10 moved down. FIGS. 4A and 4B illustrate vertical movements of the shutter 10 in conjunction with the gate valve 9.

When the gate valve 9 is closed, as shown in FIG. 4A, the shutter 10 shields the cutoff portion 4b. When the gate valve 9 is opened, as shown in FIG. 4B, the shutter 10 is moved down to disclose the cutoff portion 4b. When the gate valve 9 is closed, the shutter 10 is moved up to shield the cutoff portion 4b as shown in FIG. 4A.

Further, as shown in cross sectional views of FIGS. 4A and 4B, a surface 10c of the shutter 10 facing the processing space 1 has a width and height different from those of a surface 10d of the shutter 10 facing the loading/unloading port 2f. In this embodiment, the surface 10c facing the processing space 1 has a width and height respectively smaller than those of the surface 10d facing the loading/unloading port 2f. Further, the surface 10c has a width and height respectively smaller than those of the cutoff portion 4b such that the surface 10c is received in the cutoff portion 4b.

On the contrary, the surface 10d facing the loading/unloading port 2f has a width and height larger than those of the cutoff portion 4b such that the surface 10d overlaps with a peripheral portion of the cutoff portion 4b. Accordingly, it is possible to eliminate a clearance passing straight from the processing space 1 to the loading/unloading port 2f between the cutoff portion 4b and the shutter 10.

In this embodiment, the clearance between the cutoff portion 4b and the shutter 10 is bent. By bending the clearance, the portion of the sidewall 2a in the vicinity of the loading/unloading port 2f, the inner wall of the loading/unloading port 2f and the gate valve 9 are not seen directly from the processing space 1. Accordingly, compared to a case in which a straight clearance is present between the shutter 10 and the cutoff portion 4b, it is possible that the portion of the sidewall 2a in the vicinity of the loading/unloading port 2f, the inner wall of the loading/unloading port 2f and the gate valve 9 are hardly exposed to the processing space 1.

A processing gas inlet opening 2g is formed at the lid 2d of the processing container 2 to introduce a processing gas into the processing space 1. The processing gas inlet opening 2g passes through the sidewall 2a. In this embodiment, the cylindrical portion 4a of the ceiling plate is formed along the sidewall 2a. In this state, the processing gas inlet opening 2g is obstructed by the cylindrical portion 4a and, thus, the processing gas cannot be introduced into the processing space 1.

Therefore, the following study is proposed in this embodiment. FIG. 5 illustrates an enlarged cross sectional view of the periphery of the processing gas inlet opening 2g.

As shown in FIG. 5, the clearance 4c is set between the cylindrical portion 4a and the sidewall 2a. A processing gas 2h injected from the processing gas inlet opening 2g collides with the cylindrical portion 4a and is directed to the bottom surface 4d of the cylindrical portion 4a through the clearance 4c. The processing gas 2h is injected into the processing space 1 through an area below the bottom surface 4d.

In order to efficiently form a flow of the processing gas 2h, a first flow path forming member 11 is provided between the cylindrical portion 4a and the sidewall 2a of the processing container 2. The first flow path forming member 11 is made of, e.g., high purity quartz.

The first flow path forming member 11 has a cylindrical shape in the same way as the cylindrical portion 4a. The first flow path forming member 11 has a vertical portion 11a extending vertically in a curtain shape along the cylindrical portion 4a. Further, the first flow path forming member 11 includes a cutoff portion not to interrupt loading/unloading of the target substrate W at the loading/unloading port 2f in the same way as the cylindrical portion 4a. The first flow path forming member 11 having the vertical portion 11a guides the processing gas 2h toward the bottom surface 4d of the cylindrical portion 4a along the cylindrical portion 4a.

Further, the first flow path forming member 11 has a horizontal portion 11b extending horizontally below the bottom surface 4d. The processing gas 2h changes its flowing direction from the vertical direction to the horizontal direction by the horizontal portion lib, and is introduced into the processing space 1 through the area below the bottom surface 4d. Thus, a processing gas inlet section is provided at an annular and slit-shaped gap between the quartz plate 6 and the bottom surface 4d of the cylindrical portion 4a.

A bias voltage may be applied to the substrate mounting table 3. For example, when the processing container 2 has a ground potential, a potential different from the ground potential is supplied to the substrate mounting table 3. A potential difference between the potential supplied to the substrate mounting table 3 and the ground potential becomes a bias voltage of the substrate mounting table 3.

Meanwhile, in the plasma processing apparatus 100 in accordance with this embodiment, the sidewall 2a of the processing container 2 is covered with the cylindrical portion 4a made of quartz, i.e., a dielectric, as shown in FIG. 5. Accordingly, since the dielectric is present between the substrate mounting table 3 and the processing container 2, it may be difficult to apply a stable bias voltage to the substrate mounting table 3.

In this regard, a second flow path forming member 2i made of metal such as aluminum, an aluminum alloy or the like, is provided at the processing container 2 to extend to the vicinity of the substrate mounting surface 3a of the substrate mounting table 3, in the present embodiment. The second flow path forming member 2i is formed integrally with the grounded lid 2d to extend in a curtain shape along the cylindrical portion 4a between the first flow path forming member 11 and the cylindrical portion 4a. The second flow path forming member 2i may be formed separately from the lid 2d.

As described above, by providing the second flow path forming member 2i extending to the vicinity of the substrate mounting surface 3a to form a ground potential point in the vicinity of the substrate mounting table 3, although the cylindrical portion 4a made of a dielectric is present between the substrate mounting table 3 and the processing container 2, it is possible to apply a stable bias voltage to the substrate mounting table 3.

Further, although the second flow path forming member 2i is represented by a dashed double-dotted line in FIG. 5, the second flow path forming member 2i formed integrally with the grounded lid 2d is represented by a solid line in FIG. 1B.

The quartz plate 6 is horizontally provided between the bottom surface 4d of the cylindrical portion 4a and the bottom wall 2b of the processing container 2 to shield the bottom wall 2b of the processing container 2 from the processing space 1. The quartz plate 6 is provided with a gas exhaust path la for evacuating the processing space 1. In this embodiment, a gas exhaust opening 6a serving as the gas exhaust path la is formed below the substrate mounting table 3.

Specifically, in this embodiment, the gas exhaust path la is formed between inner peripheral portions (represented by reference numerals 6e, 6g and 6a) of the quartz plate 6 and an outer peripheral portion (represented by reference numeral 3b) of the substrate mounting table 3. Further, by forming the gas exhaust opening 6a below the substrate mounting table 3, the gas exhaust opening 6a can be shielded by the substrate mounting table 3.

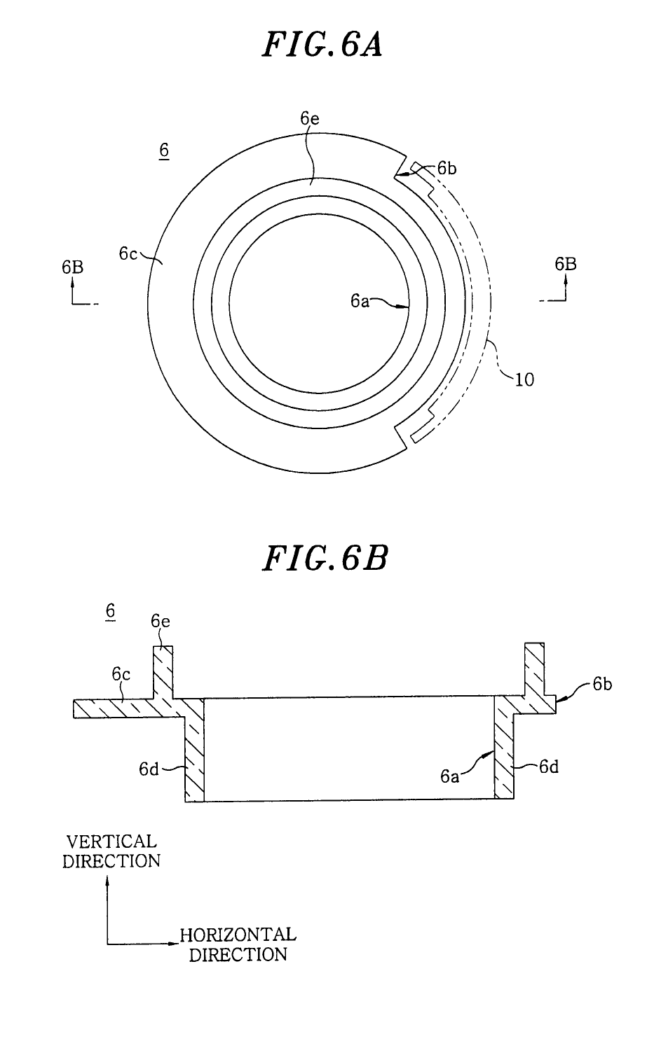

By shielding the gas exhaust opening 6a by using the substrate mounting table 3, the bottom wall 2b is prevented from being exposed directly to the processing space 1. Accordingly, the bottom wall 2b can be surely shielded from the processing space 1 compared to a case in which the gas exhaust opening 6a is provided at a position other than a position below the substrate mounting table 3. A plan view of the quartz plate 6 is illustrated in FIG. 6A.

As shown in FIG. 6A, the quartz plate 6 has a circular shape and the gas exhaust opening 6a is formed at a central portion of the quartz plate 6. In this embodiment, there is no opening other than the gas exhaust opening 6a. Further, the quartz plate 6 has a cutoff portion 6b at a position corresponding to the loading/unloading port 2f in the same manner as the cylindrical portion 4a. The shutter 10 is arranged in the cutoff portion 6b. A cross sectional view taken along line 6B-6B of FIG. 6A is illustrated in FIG. 6B.

As shown in FIG. 6B, the quartz plate 6 includes a horizontal portion 6c extending horizontally and a vertical portion 6d extending vertically from the periphery of the gas exhaust opening 6a to the gas exhaust room 7. The horizontal portion 6c shields the bottom wall 2b from the processing space 1. The vertical portion 6d shields a portion of the sidewall 2a below the substrate mounting table 3 from the processing space 1. Further, the vertical portion 6d extends to the inside of the opening 2e of the processing container 2 as shown in FIG. 1B and shields an inner wall exposed in the opening 2e from the processing space 1. Furthermore, the vertical portion 6d is provided at the periphery of the gas exhaust opening 6a to form a gas exhaust path from the processing space 1.

A protrusion 6e is formed on an upper surface of the horizontal portion 6c. The protrusion 6e protrudes between the side surface of the cylindrical portion 4a and the side surface of the substrate mounting table 3. The side surface of the protrusion 6e, particularly as shown in FIG. 5, faces an area between the horizontal portion 11b of the first flow path forming member 11 and the bottom surface 4d of the cylindrical portion 4a, i.e., a slit-shaped gap 4e for introducing the processing gas 2h into the processing space 1.

The processing gas 2h injected from the gap 4e changes its flowing direction from the horizontal direction to the vertical direction toward an upper side of the processing space 1. Accordingly, the processing gas 2h is injected to the upper side of the processing space 1 from an annular and slit-shaped gap 6f formed between the side surface of the cylindrical portion 4a and the protrusion 6e. In this embodiment, the slit-shaped gap 4e for introducing the processing gas 2h into the processing space 1 is arranged at a position lower than the substrate mounting table 3. In this configuration, it may be difficult to efficiently supply the processing gas 2h to the target substrate W mounted on the substrate mounting table 3.

In the present embodiment, however, since the protrusion 6e is provided on the upper surface of the horizontal portion 6c of the quartz plate 6 and the processing gas inlet section for introducing the processing gas into the processing space 1 is configured to inject the processing gas from an outer periphery of the substrate mounting table 3 toward the upper side of the processing space 1, it is possible to efficiently supply the processing gas 2h to the target substrate W mounted on the substrate mounting table 3. Further, a gas in the processing space 1 is exhausted from the outer periphery of the substrate mounting table 3 through an area below the substrate mounting table 3.

Further, particularly in this embodiment, a quartz cover 12 made of high purity quartz is provided over an inner wall of the gas exhaust room 7 from the opening 2e formed at the bottom wall 2b, as shown in FIG. 1B. The quartz cover 12 shields the inner wall of the gas exhaust room 7 from the processing space 1.

The inner wall of the gas exhaust room 7 is not directly seen from the processing space 1. However, when lift pins for moving the target substrate W up and down are provided at the substrate mounting table 3, the inner wall of the gas exhaust room 7 may be directly seen from the processing space 1. Although not shown in FIGS. 1A to 6B, the lift pins are inserted into lift pin holes formed through the substrate mounting table 3. The inner wall of the gas exhaust room 7 may be seen from the processing space through the lift pin holes. In this case, it is preferable that the quartz cover 12 is provided over the inner wall of the gas exhaust room 7 from the opening 2e formed at the bottom wall 2b.

In this embodiment, the microwave antenna 5 coupled to the ceiling plate 4 is a planar antenna. The microwave radiated from the planar antenna is propagated to the processing space 1 via the ceiling plate 4. A specific example of the planar antenna is a radial line slot antenna (RLSA) shown in FIG. 1B.

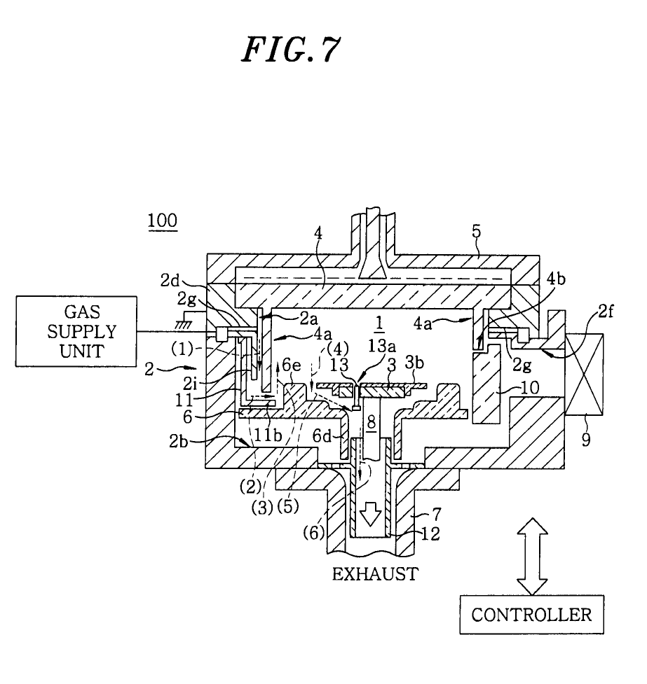

FIG. 7 illustrates a specific example of the RLSA plasma processing apparatus in accordance with the embodiment of the present invention. In FIG. 7, the same reference numerals are given to the same components as those in FIGS. 1A to 6B, and a description thereof is omitted.

As shown in FIG. 7, in this apparatus, a stage cover 3b made of, e.g., high purity quartz is provided on the substrate mounting table 3. Further, there are vertical movable lift pins 13, e.g., three lift pins 13 (only one is shown in the drawing). Lift pin holes 13a are formed at the substrate mounting table 3 and the stage cover 3b to pass the lift pins 13 therethrough.

Further, the protrusion 6e of the quartz plate 6 is provided to face the cylindrical portion 4a and an upper end of the protrusion 6e is made rounded. By making the upper end of the protrusion 6e rounded, it is possible to efficiently guide the processing gas from the outer periphery of the substrate mounting table 3 toward the upper side of the processing space 1 above the target substrate W.

Further, a space is provided between the protrusion 6e and the periphery of the stage cover 3b, the space serving as the gas exhaust path. The space extends obliquely from an area below the stage cover 3b to an area below the substrate mounting table 3, and extends vertically downwardly from the area below the substrate mounting table 3. Furthermore, by making the upper end of the protrusion 6e rounded, it is possible to efficiently exhaust the processing gas from the outer periphery of the substrate mounting table 3 toward the area below the substrate mounting table 3.

In the apparatus shown in FIG. 7, flows (1) to (3) of introduction of the processing gas and flows (4) to (6) of exhaust of the processing gas are as follows.

(1) a downward flow between the side surface of the cylindrical portion 4a and the second flow path forming member 2i (first flow path)

(2) a horizontal flow between the bottom surface of the cylindrical portion 4a and the horizontal portion 11b of the first flow path forming member 11 (second flow path)

(3) an upward flow between the side surface of the protrusion 6e and the side surface of the cylindrical portion 4a (third flow path)

(4) a downward flow between the side surface of the protrusion 6e and the periphery of the stage cover 3b (first exhaust path)

(5) a downward oblique flow between the quartz plate 6 and the lower sides of the stage cover 3b and the substrate mounting table 3 (second exhaust path)

(6) a downward flow along the vertical portion 6d of the quartz plate 6 below the substrate mounting table 3 (third exhaust path)

A process for forming a silicon oxide film was conducted as a test example by using the apparatus shown in FIG. 7. More specifically, an Ar/O₂ plasma oxidation process using oxygen as a processing gas and argon as a dilution gas was conducted and thicknesses (expressed in angstrom (Å)) of the silicon oxide films were measured for various parameter sets of oxygen concentration (O₂ concentration) and pressure. The oxidation process was conducted under the following conditions:
a process time: 360 seconds
a temperature of the substrate mounting table 3: 400□
a flow rate: 500 to 1000 sccm (e.g., 1000 sccm, 500 sccm at O₂ concentration of 100%)
a power density: 0.41 to 4.19 W/cm² (e.g., 2.85 W/cm²)
a microwave power: 500 to 5000 W

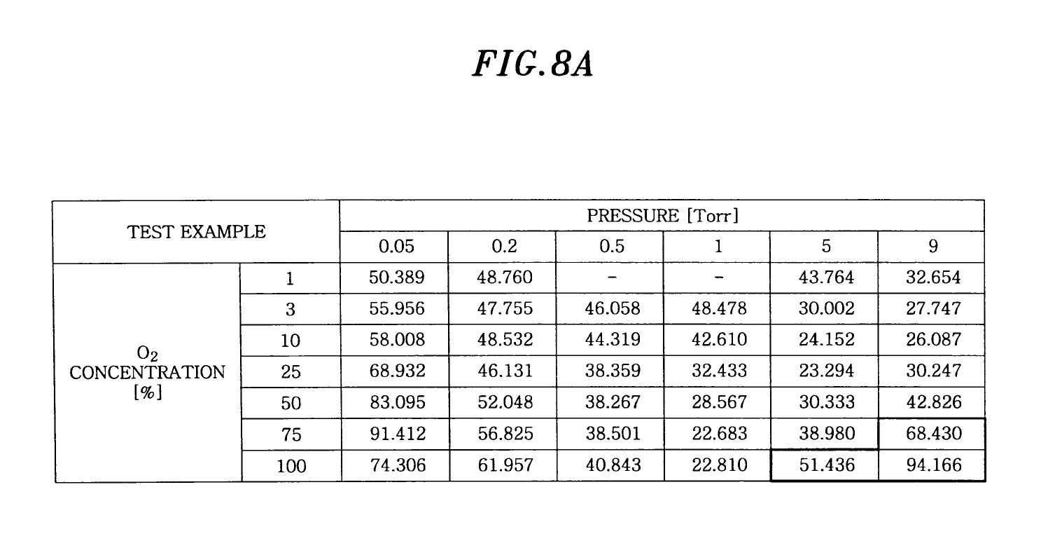

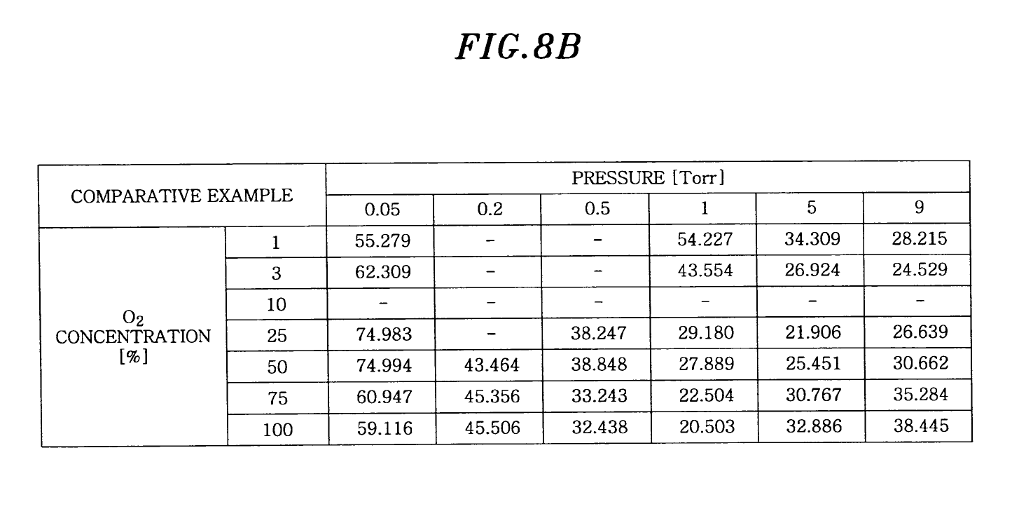

The results of the test example are shown in FIG. 8A. Further, as a comparative example, FIG. 8B illustrates the results of a process for forming a silicon oxide film by using a conventional apparatus in which the cylindrical portion 4a is not provided. The test content and the process conditions are the same as those of the above-mentioned test example. In FIGS. 8A and 8B, blanks represent cases in which evaluation was impossible due to an unstable plasma.

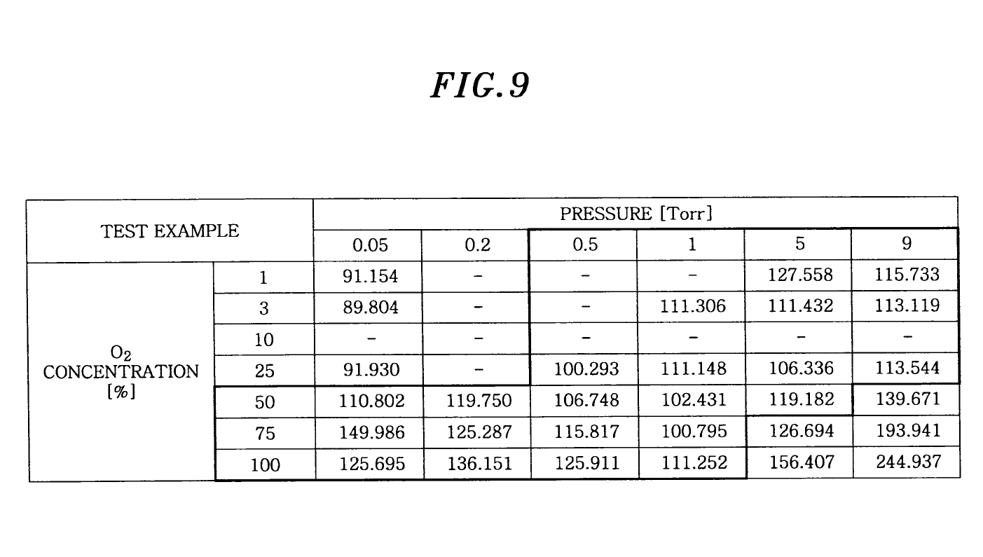

FIG. 9 illustrates the results of comparison between the results of FIG. 8A and the results of FIG. 8B, i.e., values obtained by an equation: (the film thickness of the test example/the film thickness of the comparative example)×100(%).

As shown in FIG. 9, it was found from the results of comparison that the oxidation rate of the test example is lower than that of the comparative example at a low pressure (e.g., 0.05 Torr) and a low oxygen concentration (e.g., less than 25%), whereas the oxidation rate of the test example is higher than that of the comparative example at an oxygen concentration of 50% or more, regardless of the pressure.

Further, it can be seen that the oxidation rate of the test example is higher than that of the comparative example at a pressure of 0.5 Torr or more, regardless of the oxygen concentration.

As described above, with the plasma processing apparatus in accordance with the embodiment of the present invention, it is possible to achieve not only an effect of prevention of metal contamination, but also an advantage of a high oxidation rate, particularly, at a high oxygen concentration and a high pressure.

Especially, as shown in FIG. 8A, the thicknesses of the silicon oxide films formed at a pressure of 5 Torr and an oxygen concentration of 100% and at a pressure of 9 Torr and oxygen concentrations of 75% and 100% all exceed 50 angstrom (5 nm), which means that the oxidation rate is increased by 56% to 144% compared to the comparative example. Particularly, when the pressure is 9 Torr and the oxygen concentration is 100%, the silicon oxide film is formed to have a thickness of 94.166 angstrom (about 9.4 nm), which exhibits a maximum oxidation rate. A high oxidation rate at a high pressure, particularly, a high oxidation rate twice or more that of the comparative example at a pressure of 9 Torr, contributes to improvement in the processing rate, which is advantageous in a semiconductor process in the future.

Further, as shown in FIG. 9, a 25% increase in the oxidation rate under the high oxygen concentration and the high pressure, which is an optimal condition for the process, is obtained at a pressure of 5 Torr or more and an oxygen concentration of 75% or more and at a pressure of 9 Torr or more and an oxygen concentration of 50% or more, as shown in FIG. 9.

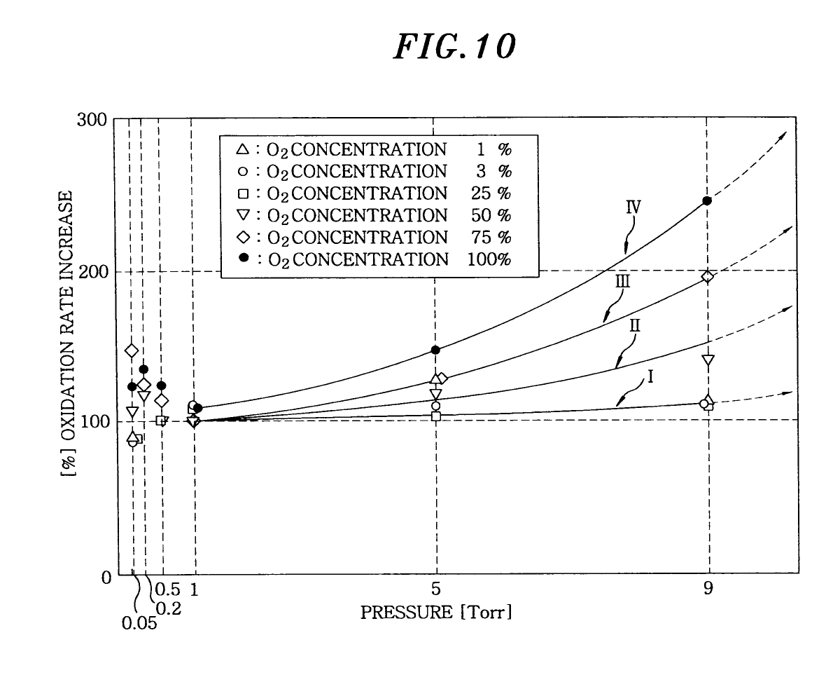

FIG. 10 is a graph showing the results of FIG. 9.

As shown in FIG. 10, the oxidation rate is improved compared to the comparative example at a pressure of 0.5 Torr or more regardless of the oxygen concentration (0₂ concentration).

Further, it was found that the oxidation rate increases as the oxygen concentration increases at a pressure of 0.5 Torr or more, particularly, 1 Torr or more, and an oxygen concentration of 25% or more.

In FIG. 10, curves I and II represent cases of oxygen concentrations of 25% and 50%, respectively, and curves III and IV represent cases of oxygen concentrations of 75% and 100%, respectively. As represented by curves I to IV, the oxidation rate increases as the oxygen concentration increases at a pressure of 0.5 Torr or more, particularly, 1 Torr or more, and an oxygen concentration of 25% or more.

From the results of FIG. 10, it is concluded that a plasma processing method capable of forming oxide at a high rate is obtained by setting a pressure of 0.5 Torr or more and an oxygen concentration of 25% or more while forming a silicon oxide film.

It is thought that this conclusion is caused by a difference in a diffusion path of the processing gas in which the processing gas is introduced from a vicinity of the outer periphery of the substrate, and a difference in a shape of the processing space 1 in which metal members in the processing container is prevented from being exposed to the processing space.

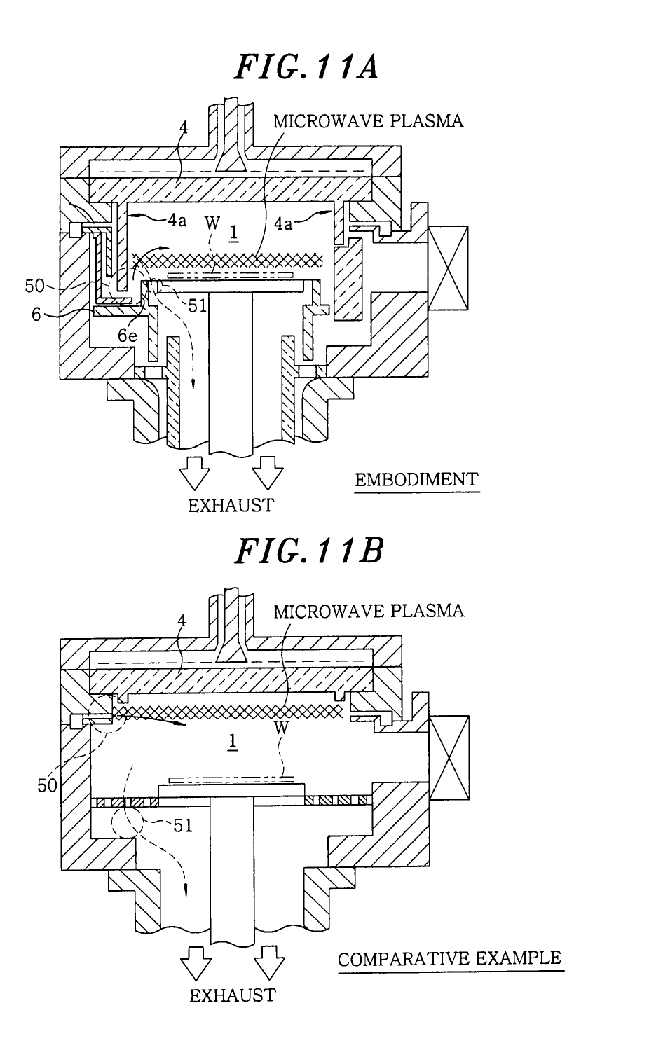

FIG. 11A is a cross sectional view schematically showing the apparatus in accordance with the embodiment of the present invention. FIG. 11B is a cross sectional view schematically showing the apparatus of the comparative example.

The apparatuses shown in FIGS. 11A and 11B have the following differences. That is, the apparatus in accordance with the embodiment of the present invention has the cylindrical portion 4a and the apparatus of the comparative example does not have the cylindrical portion 4a. In the apparatus of the embodiment of the present invention, a supply place 50 of the processing gas is arranged laterally below the target substrate W and, accordingly, a conductance of the gas exhaust path is reduced. In contrast, the supply place 50 of the processing gas is arranged above the target substrate W in the apparatus of the comparative example.

Meanwhile, a gas exhaust place 51 is arranged below the target substrate W in both the apparatuses. However, an exhaust flow is formed above the outer periphery of the target substrate W in the configuration of the comparative example in which a baffle plate is provided at the outer periphery of the mounting table. In the apparatus of the embodiment of the present invention, by contrast, a gas exhaust path is formed between the quartz plate 6 and the area below the mounting table.

Accordingly, a distance from the supply place 50 to the exhaust place 51 of the processing gas is small in the apparatus of the embodiment of the present invention, whereas the distance from the supply place 50 to the exhaust place 51 (i.e., from the upper side of the processing space 1 to the lower side of the processing space 1) is large in the comparative example. Furthermore, in the embodiment of the present invention, the exhaust place 51 of the processing gas is arranged at a position higher than the position of the supply place 50 of the processing gas.

The following conjecture can be made from above-described differences.

In the embodiment of the present invention, both the supply place 50 and the exhaust place 51 of the processing gas are arranged on the lateral and lower sides of the processing space 1. Further, the position of the exhaust place 51 is higher than the position of the supply place 50. Besides, the supply place 50 and the exhaust place 51 adjoin each other with the protrusion 6e of the quartz plate 6 between them. Accordingly, the distance from the supply place 50 to the exhaust place 51 is small, so that the processing gas supplied to the processing space 1 can be exhausted immediately and only a minimum amount of processing gas required for a plasma process such as an oxidation process can be diffused into the processing space 1.

Moreover, since the supply place 50 and the exhaust place 51 adjoin each other with the protrusion 6e between them, the processing gas supplied from the supply place 50 passes through the area above the exhaust place 51 before it reaches the area above the target substrate W. Accordingly, the supplied processing gas is partially exhausted before it reaches the area above the target substrate W. Thus, only a minimum amount of the processing gas necessary for the plasma process is diffused to the area above the target substrate W and a gas unnecessary for the plasma process is exhausted.

Generally, 10% or less of the processing gas supplied to the processing space 1 is actually used in the plasma process. 90% or more of the processing gas is unnecessary and the unnecessary gas may hinder a plasma process such as an oxidation process. However, in this embodiment, since the unnecessary gas is hardly diffused to the area above the target substrate W, a processing rate such as an oxidation rate does not decrease even under a high pressure. Far from decreasing, as shown in FIGS. 9 and 10, the processing rate (oxidation rate) was mostly improved.

By comparison, in the comparative example, the supply place 50 of the processing gas is arranged at the upper side of the processing space 1 and the exhaust place 51 of the processing gas is arranged at the lower side of the processing space 1. Accordingly, the distance from the supply place 50 to the exhaust place 51 is large and most of the supplied processing gas is diffused into the processing space 1. In the comparative example, the processing gas supplied to the processing space 1 passes through the area above or around the target substrate W. Accordingly, a gas unnecessary for a plasma process tends to be diffused to the area above or around the target substrate W. Particularly, under a high pressure, an amount of unnecessary gas becomes larger, thereby hindering oxidation.

Further, in the embodiment of the present invention, the cylindrical portion 4a made of quartz, i.e., a dielectric, is extended to the lateral side of the target substrate W. Accordingly, the entire target substrate W (the area above and around the target substrate W) is enclosed by the dielectric in the processing space 1. The microwave passes through the dielectric.

As described above, the side surface and the upper surface of the target substrate W are enclosed by the dielectric allowing the microwave to pass therethrough. By supplying the microwave through the dielectric and supplying the processing gas from a lower lateral side of the target substrate W (the substrate mounting table 3), a microwave plasma can be generated in the closest position to the target substrate W. Since the concentration of the processing gas is high above the upper surface of the target substrate W and the microwave plasma is generated in the closest position to the target substrate W, efficiency of the oxidation process can be improved.

By comparison, in the comparative example, only the ceiling plate 4 is a dielectric and the processing gas is supplied from the upper side of the processing gas. Accordingly, a microwave plasma is easily generated at the upper side of the processing space 1, that is, at a place close to the ceiling plate 4. Thus, in the comparative example, the plasma tends to be generated at a place separated from the target substrate W compared to the embodiment of the present invention, thereby reducing efficiency of the oxidation process.

From the above facts, it is conjectured that the plasma processing apparatus in accordance with the embodiment of the present invention generally has a high processing rate such as an oxidation rate, particularly, in a plasma process under high oxygen concentration and high pressure compared with the apparatus without the cylindrical portion 4a.

As described above, in the plasma processing apparatus in accordance with the embodiment of the present invention, the inner wall of the processing container 2 is covered with quartz not to be exposed to the processing space 1, thereby achieving a high processing rate.

Further, by covering the inner wall of the processing container 2 with quartz not to be exposed to the processing space 1, it is possible to reduce contamination caused by metal scattered from the inner wall of the processing container 2.

Therefore, in the plasma processing apparatus in accordance with the embodiment of the present invention, it is possible to precisely form a high quality film with a high processing rate.

While the invention has been shown and described with respect to the embodiments, various changes and modification may be made without being limited thereto. Further, the embodiment of the present invention is not limited to the above-described embodiments.

For example, although the oxidation process was described as the plasma process in the above embodiments, the apparatus in accordance with the embodiment of the present invention may be also applied to, e.g., a nitriding process, an oxidizing-nitriding process or a film forming process without being limited to the oxidation process.

Further, although the RLSA was described as the microwave antenna, a microwave antenna other than the RLSA may be used.

Further, the present invention may be applied to other plasma processing apparatuses such as a parallel plate type plasma processing apparatus, a surface wave plasma processing apparatus, a magnetron plasma processing apparatus and an inductively coupled plasma processing apparatus.

What is claimed is:

1. A plasma processing apparatus comprising:
a metallic processing container forming a processing space in which a plasma process is performed;
a substrate mounting table provided in the processing space to mount a target substrate thereon;
a quartz member which shields a sidewall of the metallic processing container from the processing space and whose lower end extends to a position lower than a substrate mounting surface of the substrate mounting table;
an annular member which is made of quartz and is provided between a bottom surface of the quartz member and a bottom wall of the metallic processing container to shield the bottom wall of the metallic processing container from the processing space; and
a processing gas inlet section for introducing a processing gas into the processing space from a vicinity of an outer periphery of the substrate mounting table.

2. A plasma processing apparatus comprising:
a metallic processing container forming a processing space in which a plasma process is performed;
a substrate mounting table provided in the processing space to mount a target substrate thereon;
a quartz ceiling plate provided at an upper portion of the processing container to face a substrate mounting surface of the substrate mounting table and having a cylindrical portion which shields a sidewall of the metallic processing container from the processing space;
a microwave antenna coupled to the quartz ceiling plate;
a quartz plate which is provided between a bottom surface of the cylindrical portion and a bottom wall of the metallic processing container to shield the bottom wall of the metallic processing container from the processing space; and
a processing gas inlet section for introducing a processing gas into the processing space from a vicinity of an outer periphery of the substrate mounting table.

3. The plasma processing apparatus of claim 2, wherein the quartz plate has a gas exhaust opening formed below the substrate mounting table to exhaust a gas in the processing space from below the substrate mounting table.

4. The plasma processing apparatus of claim 2, wherein the quartz plate has a protrusion provided between a side surface of the cylindrical portion and a side surface of the substrate mounting table.

5. The plasma processing apparatus of claim 4, wherein the cylindrical portion has a portion facing the protrusion.

6. The plasma processing apparatus of claim 2, further comprising:
a gas inlet opening formed at the sidewall of the metallic processing container to introduce the processing gas into the processing space; and
a gas flow path forming member which is provided between the cylindrical portion and the sidewall of the metallic processing container, guides the processing gas toward a bottom surface of the cylindrical portion along the cylindrical portion, and introduces the processing gas into the processing space through an area below the bottom surface of the cylindrical portion.

7. The plasma processing apparatus of claim 2, further comprising:
an opening formed at the bottom wall of the metallic processing container;
a metallic exhaust room connected to the opening and a gas exhaust unit; and
a quartz cover which is provided over an inner wall of the metallic exhaust room from the opening formed at the bottom wall to shield the inner wall of the metallic exhaust room from the processing space.

8. The plasma processing apparatus of claim 2, further comprising:
a loading/unloading port which is formed at the sidewall of the metallic processing container and through which the target substrate is loaded into/unloaded from the processing space;
a cutoff portion formed at a portion of the cylindrical portion corresponding to the loading/unloading port; and
a shutter made of quartz and provided between the cutoff portion and the loading/unloading port.

9. The plasma processing apparatus of claim 2, wherein the microwave antenna is a planar antenna.

10. The plasma processing apparatus of claim 9, wherein the planar antenna is a radial line slot antenna (RLSA).

11. The plasma processing apparatus of claim 2, wherein the plasma processing apparatus is an apparatus for forming a silicon oxide film.

12. A plasma processing method for forming a film by using a microwave plasma, comprising:
supplying a microwave to a dielectric enclosing an outer periphery or an upper surface of a target substrate and allowing a microwave to pass therethrough; and
supplying a processing gas from the outer periphery of or below the target substrate while the microwave is supplied to the dielectric.

13. The plasma processing method of claim 12, wherein the processing gas is supplied to an area above the target substrate after passing through an area above a gas exhaust port through which the processing gas is exhausted.

14. The plasma processing method of claim 12, wherein the film to be formed is a silicon oxide film.

15. The plasma processing method of claim 14, wherein the processing gas for forming the silicon oxide film has an oxygen concentration of 50% or more.

16. The plasma processing method of claim 14, wherein the silicon oxide film is formed at a pressure of 0.5 Torr or more.

17. The plasma processing method of claim 16, wherein the processing gas for forming the silicon oxide film has an oxygen concentration of 25% or more.

18. The plasma processing method of claim 12, wherein the processing gas is exhausted from the outer periphery of and below the target substrate.

19. The plasma processing method of claim 18, wherein a position of an exhaust place of the processing gas is higher than a position of a supply place of the processing gas.
